(19) United States
(12) Patent Application Publication
(10) Pub. No.: US 2025/0058823 A1
(43) Pub. Date: Feb. 20, 2025

(54) DEVICE AND METHOD FOR DETECTING ABNORMALITY OF MOTOR OF COLUMN ELECTRIC POWER STEERING (EPS), AND COMPUTER-READABLE STORAGE MEDIUM STORING PROGRAM FOR PERFORMING THE METHOD

(71) Applicant: HL MANDO CORPORATION, Gyeonggi-do (KR)

(72) Inventors: Gyuwon KIM, Gyeonggi-do (KR); Jongick WON, Gyeonggi-do (KR)

(21) Appl. No.: 18/803,710

(22) Filed: Aug. 13, 2024

(30) Foreign Application Priority Data
Aug. 14, 2023 (KR) 10-2023-0106181
Feb. 15, 2024 (KR) 10-2024-0021747

(51) Int. Cl. B62D 5/04

(52) U.S. Cl. CPC B62D 5/0487; B62D 5/0409

(57) ABSTRACT

Disclosed are a device and method for detecting an abnormality of a motor of a column electric power steering (EPS), and a non-transitory computer-readable storage medium storing a program for performing the method. The device for detecting the abnormality of the motor of the column EPS is a device for detecting an abnormality of a motor of a column EPS, which detects an abnormality of a motor of a column EPS that provides an auxiliary steering force to a steering column of an EPS system of a vehicle, and includes a memory configured to store one or more instructions, and a processor configured to execute the one or more instructions, wherein the processor executes the one or more instructions to input operation data related to steering wheel operation by a driver of the vehicle and state data indicating a state of the vehicle into an artificial neural network model, obtain an output estimated value of the motor output from the artificial neural network model, compare the estimated value with an output measurement value of the motor, and detect an abnormality of the motor.

### CROSS-REFERENCE TO RELATED APPLICATION

This application claims priority to and benefit from Korean Patent Application No. 10-2023-0106181, filed on Aug. 14, 2023, and Korean Patent Application No. 10-2024-0021747, filed on Feb. 15, 2024, the disclosures of which are incorporated herein by reference in their entireties.

### BACKGROUND

### 1. Technical Field

The present disclosure relates to a device and method for detecting an abnormality of a motor of a column electric power steering (EPS), and a non-transitory computer-readable storage medium storing a program for performing the method, and more specifically, to a device and method for detecting an abnormality of a motor of a column EPS that is capable of detecting degradation in performance of a motor, which is placed on a steering column connected to a steering wheel and provides an auxiliary steering force when a driver operates the steering wheel, and a non-transitory computer-readable storage medium storing a program for performing the method.

### 2. Discussion of Related Art

Electric power steering (EPS) systems use a motor to assist the driver's steering. Among the EPS systems, a column EPS system is configured so that an auxiliary steering force generated by a motor is provided to a steering column connected to a steering wheel of a vehicle.

When a motor generating an auxiliary steering force in a column EPS system fails, a driver will have difficulty in steering a vehicle. Accordingly, the steering may not be performed as desired by the driver, which may cause an accident.

In this way, a motor of a column EPS system is a very important element in the safety of vehicles. Therefore, in order to improve the safety of vehicles equipped with a column EPS system, it is necessary to prognosticate a decrease in output of a motor of a column EPS before the motor of the column EPS fails.

However, conventional approaches related to the fail-safety of a motor of a column EPS focus on post-failure diagnosis and follow-up measures rather than preventing a failure in advance. Further, conventional column EPS systems use the fail-safety based on the current of motors, but have a limitations that the fail safety is insufficient in terms of direct response to a decrease in output.

(Patent Document) Korean Patent Registration No. 2098049, “METHODS FOR CONTROLLING EPS THAT CUTS MOTOR DRIVE POWER WHEN OVERCURRENT OCCURS,” registered on Apr. 1, 2022

### SUMMARY

The present disclosure is directed to providing a device and method for detecting an abnormality of a motor of a column electric power steering (EPS) that is capable of prognosticating degradation in performance of a motor, which is disposed in a column EPS system of a vehicle and generates an auxiliary steering force, and a non-transitory computer-readable storage medium storing a program for performing the method.

The present disclosure is also directed to providing a device and method for detecting an abnormality of a motor of a column EPS that is capable of efficiently detecting in advance a decrease in an output of a motor of a column EPS using signals of a controller area network (CAN) in a vehicle, and a non-transitory computer-readable storage medium storing a program for performing the method.

The objects of the present disclosure are not limited to the above-described objects, and other objects that are not mentioned will be able to be clearly understood by those skilled in the art to which the present disclosure pertains from the following description.

According to an aspect of the present disclosure, there is provided a device for detecting an abnormality of a motor of a column EPS, which detects an abnormality of a motor of a column EPS that provides an auxiliary steering force to a steering column of an EPS system of a vehicle, which includes a memory configured to store one or more instructions, and a processor configured to execute the one or more instructions, wherein the processor executes the one or more instructions to input operation data related to steering wheel operation by a driver of the vehicle and state data indicating a state of the vehicle into an artificial neural network model, obtain an output estimated value of the motor output from the artificial neural network model, compare the estimated value with an output measurement value of the motor, and detect the abnormality of the motor.

The operation data may include at least one of a steering angle, a steering angular velocity, and a steering torque.

The state data may include at least one of a speed of the vehicle, a lateral acceleration of the vehicle, a yaw rate of the vehicle, and a wheel speed of the vehicle.

The operation data and the state data may consist of signals that are obtainable through a CAN of the vehicle.

The artificial neural network model may include a generative adversarial network (GAN) including a generator that receives the operation data and the state data and generates the estimated value.

The artificial neural network model may further include a discriminator that receives measurement data including the operation data, the state data, and the measurement value and outputs a discrimination value for the measurement data.

The generator may be composed of a multivariate transformer

The processor may execute the one or more instructions to input error data related to a difference between the estimated value and the measurement value into an abnormality detection model and determine whether the motor is abnormal.

The abnormality detection model may use a one-class support vector machine (OCSVM) algorithm.

There may be a plurality of data sets including the operation data, the state data, the measurement value, and the estimated value, and the error data may include a mean and standard deviation of errors between the measurement value and the estimated value that are obtained from each of the plurality of data sets, a maximum absolute error between the measurement value and the estimated value of the plurality of data sets, and a discrimination value of the discriminator for the measurement data of the plurality of data sets.

The discriminator may additionally receive estimate data including the operation data, the state data, and the estimated value, and additionally output the discrimination value for the estimate data.

The artificial neural network model may be constructed by the generator and the discriminator alternately performing learning, and the operation data, the state data, and the measurement value that are used during the learning may be obtained when the motor is in a normal state.

According to another aspect of the present disclosure, there is provided a method of detecting an abnormality of a motor of a column EPS, in which an abnormality of a motor of a column EPS that provides an auxiliary steering force to a steering column of an EPS system of a vehicle is detected, which includes inputting, by a processor, operation data related to steering wheel operation by a driver of the vehicle and state data indicating a state of the vehicle into an artificial neural network model and obtaining an output estimated value of the motor output from the artificial neural network model, and comparing, by the processor, the estimated value with an output measurement value of the motor and detecting the abnormality of the motor.

The operation data may include at least one of a steering angle, a steering angular velocity, and a steering torque.

The state data may include at least one of a speed of the vehicle, a lateral acceleration of the vehicle, a yaw rate of the vehicle, and a wheel speed of the vehicle.

The artificial neural network model may consists of a GAN including a generator that receives the operation data and the state data and generates the estimated value, and a discriminator that receives measurement data including the operation data, the state data, and the measurement value and outputs a discrimination value for the measurement data.

In the obtaining of the estimated value, the processor may input the operation data and the state data into the generator and obtain the estimated value generated by the generator.

The detecting of the abnormality of the motor may include inputting, by the processor, measurement data including the operation data, the state data, and the measurement value into the discriminator and obtaining the discrimination value for the measurement data generated by the discriminator, and inputting, by the processor, error data including the discrimination value for the measurement data and numerical values related to a difference between the estimated value and the measurement value into an abnormality detection model and obtaining an output of the abnormality detection model.

There may be a plurality of data sets including the operation data, the state data, the estimated value, and the measurement value, and the error data may include a mean and standard deviation of errors between the measurement value and the estimated value that are obtained from each of the plurality of data sets, a maximum absolute error between the measurement value and the estimated value of the plurality of data sets, and a discrimination value of the discriminator for the measurement data of the plurality of data sets.

The artificial neural network model may be constructed by the generator and the discriminator alternately performing learning, and the operation data, the state data, and the measurement value that are used during the learning may be obtained when the motor is in a normal state.

According to still another aspect of the present disclosure, there is provided a non-transitory computer-readable storage medium in which a program including at least one instruction for performing the method of detecting the abnormality of the motor of the column EPS is stored.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram schematically illustrating a configuration of a column electric power steering (EPS) system of a vehicle;

FIG. 2 is a diagram illustrating a configuration of a device for detecting an abnormality of a motor of a column EPS according to an embodiment of the present disclosure;

FIG. 3 is a diagram illustrating models that are used to obtain an estimated value or detect an abnormality in the device for detecting the abnormality of the motor of the column EPS according to the embodiment of the present disclosure;

FIG. 4 is a diagram illustrating a detailed configuration of an artificial neural network model;

FIG. 5 is a diagram illustrating a detailed configuration of a generator of the artificial neural network model;

FIG. 6 is a diagram illustrating the operation of the device for detecting the abnormality of the motor of the column EPS according to the embodiment of the present disclosure;

FIG. 7 is a flowchart of a method of detecting an abnormality of a motor of a column EPS according to an embodiment of the present disclosure; and

FIG. 8 is a detailed flowchart of an operation of detecting the abnormality of the method of detecting the abnormality of the motor of the column EPS according to the embodiment of the present disclosure.

### DETAILED DESCRIPTION OF EXEMPLARY EMBODIMENTS

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their disclosure.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

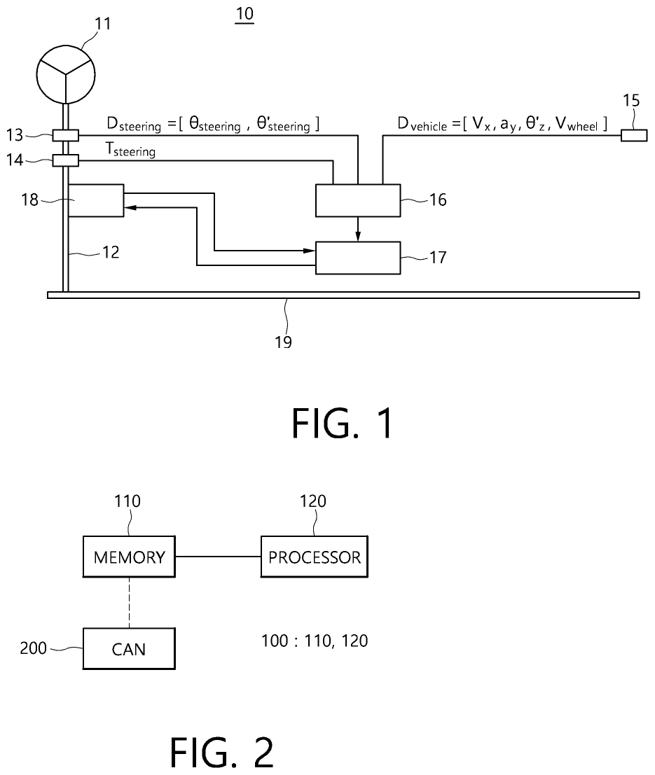

FIG. 1 is a diagram schematically illustrating a configuration of a column electric power steering (EPS) system of a vehicle.

FIG. 1 exemplarily illustrates a column EPS system 10, operation data related to steering wheel operation by a driver of a vehicle equipped with the column EPS system 10, and state data related to a driving state of the vehicle.

Referring to FIG. 1, the column EPS system 10 of the vehicle may include a steering wheel 11 operated by the driver, a steering column 12 that is connected to the steering wheel 11 and transmits a steering force to wheels of the vehicle, a steering angle sensor 13, a steering torque sensor 14 and a vehicle state measurement module 15.

The steering angle sensor 13 measures a steering angle θ_{steering} and a steering angular velocity \dot{θ}_{wsteering} of the steering wheel 11. That is, steering angle sensor information D_{steering} obtained by the steering angle sensor 13 includes the steering angle θ_{steering} and the steering angular velocity \dot{θ}_{wsteering}.

The steering torque sensor 14 measures a steering torque T_{steering}. More specifically, the steering torque sensor 14 may measure a torque applied to the steering column 12 according to the operation of the steering wheel 11.

The steering angle sensor information D_{steering} measured by the steering angle sensor 13, that is, the steering angle θ_{steering} and the steering angular velocity \dot{θ}_{wsteering}, and the steering torque T_{steering} measured by the steering torque sensor 14 may be defined as the operation data related to the steering wheel operation by the driver of the vehicle.

The vehicle state measurement module 15 includes one or more sensors that measure information related to a state of the vehicle. Vehicle state measurement module information D_{vehicle} measured by the vehicle state measurement module 15 may include a speed V_{z} of the vehicle, a lateral acceleration a_{y} of the vehicle, a yaw rate \dot{θ}_{z} of the vehicle, and a wheel speed V_{wheel} of the vehicle. Here, the wheel speed V_{wheel} of the vehicle may be measured for each of a plurality of wheels of the vehicle.

The vehicle state measurement module information D_{vehicle} may be defined as the state data indicating the state of the vehicle.

The steering angle θ_{steering} and the steering angular velocity \dot{θ}_{wsteering} that are measured by the steering angle sensor 13, the steering torque T_{steering} that is measured by the steering torque sensor 14, and the speed Vₛ of the vehicle, the lateral acceleration a_{y}, the yaw rate θ̌_{z}, and the wheel speed V_{wheel} that are measured by the vehicle state measurement module 15 are transmitted to an electronic control unit (ECU) 17 through a controller area network (CAN) 16.

The ECU 17 receives the data transmitted through the CAN 16, and performs calculations to generate a command to a motor 18 that generates an auxiliary torque to assist steering. The command is transmitted to the motor 18. In this case, the command may be provided to the motor 18 in the form of current. In this case, the ECU 17 may perform feedback control on the motor 18.

A torque input through the steering wheel 11 and a torque generated by the motor 18 are transmitted to a steering mechanism 19 connected to the wheels of the vehicle. The steering mechanism 19 is driven by the torque input through the steering wheel 11 and the torque generated by the motor 18. When the steering mechanism 19 is driven, the direction of the wheels of the vehicle is adjusted and the vehicle is steered.

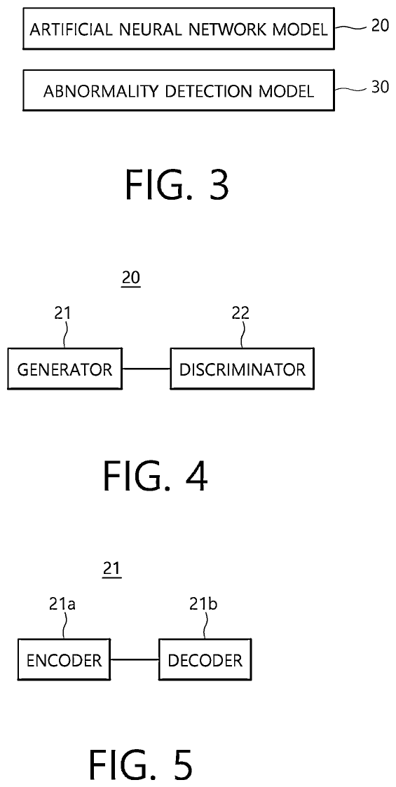

FIG. 2 is a diagram illustrating a configuration of a device for detecting an abnormality of a motor of a column EPS according to an embodiment of the present disclosure. Further, FIG. 3 is a diagram illustrating models that are used to obtain an estimated value or detect an abnormality in the device for detecting the abnormality of the motor of the column EPS according to the embodiment of the present disclosure.

A device 100 for detecting the abnormality of the motor of the column EPS according to the embodiment of the present disclosure detects an abnormality of a motor 18 that generates an auxiliary steering force in the column EPS system of the vehicle. More specifically, the device 100 for detecting the abnormality of the motor of the column EPS may detect a decrease in output of the motor 18 or an abnormality of the motor 18.

The device 100 for detecting the abnormality of the motor of the column EPS according to an embodiment of the present disclosure may detect degradation in function of the motor 18 before a failure of the motor 18 occurs using a digital twin algorithm for a vehicle based on artificial intelligence. The digital twin algorithm may virtually build the column EPS system of the vehicle.

For example, the device 100 for detecting the abnormality of the motor of the column EPS according to the embodiment of the present disclosure may be disposed in the ECU 17 of the column EPS system 10 illustrated in FIG. 1. Of course, this is an example, and the device 100 for detecting the abnormality of the motor of the column EPS may be disposed elsewhere.

Referring to FIG. 2, the device 100 for detecting the abnormality of the motor of the column EPS according to the embodiment of the present disclosure may include a memory 110 and a processor 120.

The memory 110 stores one or more instructions. The one or more instructions may configure a program for detecting an abnormality of the motor of the column EPS. The one or more instructions stored in the memory 110 may be executed by the processor 120.

The memory 110 may include a hardware device configured to store the one or more instructions. For example, the memory 110 may include a storage medium, such as a read-only memory (ROM), a random access memory (RAM), a flash memory, etc. Further, the memory 110 may include a magnetic medium such as a floppy disk or a magnetic tape, an optical medium such as a compact disc read only memory (CD-ROM) or a digital video disc (DVD), a magneto-optical medium such as a floptical disk, etc.

The processor 120 executes the one or more instructions. For example, the processor 120 may be a hardware unit that performs calculations and control. The processor 120 may include at least one arithmetic logic unit (ALU) and a register.

The processor 120 executes the one or more instructions to input operation data related to steering wheel operation by a driver of the vehicle and state data indicating a state of the vehicle into an artificial neural network model 20 and obtains an output estimated value of the motor 18 that is output by the artificial neural network model 20.

The operation data may include at least one of a steering angle θ_{steering}, a steering angular velocity \dot{θ}_{steering}, and a steering torque T_{steering}. As described above, the steering angle θ_{steering} and the steering angular velocity \dot{θ}_{steering} may be measured by the steering angle sensor 13, and the steering torque T_{steering} may be measured by the steering torque sensor 14.

The state data may include at least one of a speed Vₓ of the vehicle, a lateral acceleration a_{y}, a yaw rate \dot{θ}_{z}, and a wheel speed V_{wheel} of the vehicle. Meanwhile, when the vehicle has a plurality of wheels, the wheel speed may be obtained for each of the plurality of wheels.

All of the operation data and the state data described above may be obtained through a CAN 200. In other words, the operation data and the state data may consist of signals that can be obtained through the CAN 200 of the vehicle. Accordingly, according to the present disclosure, an abnormality of the motor may be efficiently detected without the use of an additional sensor in relation to detecting an abnormality of the motor of the column EPS.

In this regard, the memory 110 may be directly or indirectly connected to the CAN 200 of the vehicle. The memory 110 may receive the operation data and the state data from the CAN 200. Accordingly, the processor 120 may obtain the operation data and the state data from the memory 110.

The artificial neural network model 20 receives the operation data and the state data and outputs the output estimated value of the motor 18. In an embodiment of the present disclosure, the artificial neural network model 20 may include a generative adversarial network (GAN).

In an embodiment of the present disclosure, the artificial neural network model 20 may be a deep learning-based neural twin model for the column EPS system of the vehicle. In other words, the artificial neural network model 20 may serve as a virtual twin model of the EPS system of the vehicle.

FIG. 4 is a diagram illustrating a detailed configuration of the artificial neural network model.

Referring to FIG. 4, the artificial neural network model 20 may include a generator 21 and a discriminator 22.

The artificial neural network model 20 may be constructed by the generator 21 and the discriminator 22 alternately performing learning. In this case, data used when learning is performed may be obtained when the motor 18 of the column EPS system 10 is in a normal state. Accordingly, the estimated value output by the artificial neural network model 20 may follow an output measurement value of the motor obtained when the motor 18 is in a normal state.

The generator 21 receives the operation data and the state data and generates the output estimated value of the motor 18. The generator 21 may include a neural network. The generator 21 may be composed of a multivariate transformer. That is, the artificial neural network model 20 may be a GAN based on a multivariate transformer.

The generator 21 may calculate the operation data and the state data and output the output estimated value of the motor 18 of the column EPS system. The output estimated value estimated by the generator 21 follows an output value of the motor output to correspond to the operation data and the state data when the column EPS system is in a normal state.

FIG. 5 is a diagram illustrating a detailed configuration of the generator of the artificial neural network model.

Referring to FIG. 5, the generator 21 may include an encoder 21a and a decoder 21b.

The encoder 21a and the decoder 21b form a network for obtaining an output estimated value of an output of the motor. In other words, the generator 21 may be composed of an encoder 21a-decoder 21b structured network trained in an end-to-end manner to estimate the estimated value.

The encoder 21a may be designed to extract high-level features from the operation data and the state data using a transformer block and linear operation.

In this case, the transformer block may include an embedding layer, a self-attention layer, and a feed-forward layer.

First, the embedding layer in the transformer block may encode spatiotemporal information into input sequences using a trainable embedding matrix.

Next, deep features may be extracted through the self-attention layer, and refinement may be performed using the feed-forward layer.

In this case, the self-attention layer may utilize a scaled dot-product attention mechanism. The self-attention layer may be a key component in transformer-based deep neural network (DNN) architectures, allowing the model to process and understand dependencies within the input sequence.

Scaled dot-product attention may first apply layer normalization to the input sequence and process results of the layer normalization into three unique vectors: a query (Q); a key (K); and a value (V) through linear operations.

Next, an attention score AS may be calculated for each position in the input sequence on the basis of the derived vectors. A calculation formula for the attention score AS may be given as Formula 1 below.

$$AS = σ ( \frac{Q \cdot K}{\sqrt{{‖ {x}_{input} ‖}_{dim}}} ) \cdot V \qquad ( Formula 1 )$$

(σ( ) denotes a softmax operation, |xᵢₙₚᵤₜ|_{dim} denotes a feature dimension of an input, and denotes a dot product.)

An attention score quantifies the relative importance of each position in the input sequence relevant to a given query. That is, higher scores are assigned to more appropriate positions.

An output of the transformer block may be fed to two different linear operations to calculate a query, a key vector, and an initial input value of the decoder 21b.

The decoder 21b may estimate the estimated value using the obtained values in an auto-regressive manner similar to sequence-to-sequence recurrent neural networks.

Like the encoder 21a, the decoder 21b may include a transformer block and linear operations. Additionally, the decoder 21b may include a cross-attention layer within the transformer block.

The cross-attention layer may perform scaled dot-product attention using the query and key vector of the encoder 21a to learn a dynamic correlation between input signals and estimated signals.

The discriminator 22 receives measurement data including the operation data, the state data, and the output measurement value of the motor and outputs a discrimination value for the measurement data.

The discriminator 22 is a classifier that aims to determine the conditional probability. The discriminator 22 determines the probability of an example being real or fake given that set of input features. The discrimination value from the discriminator 22 are classification labels. For example, the discrimination value from the discriminator 22 is 0 or 1.

Meanwhile, the discriminator 22 may additionally receive estimate data including the operation data, the state data, and the output estimated value of the motor and additionally output a discrimination value for the estimate data. Such a process may be accomplished when the generator 21 and the discriminator 22 perform learning.

In this way, the discriminator 22 may output the discrimination value for the measurement data during an operation process for abnormality detection, while the discriminator 22 may output the discrimination value for the estimate data during an operation process for learning.

The discriminator 22 may be composed of a discriminator network used for adversarial training of a GAN. In other words, the generator 21 and the discriminator 22 may be trained using an adversarial training method to improve estimation performance and establish a GAN model.

More specifically, the discriminator 22 may perform optimization alternately with the generator 21 to solve a Wasserstein min-max problem such as Formula 2.

$${min}_{G} {max}_{D} {E}_{{x}_{D , Real}} [ D ( {x}_{D , Real} ) ] - {E}_{{x}_{D , Fake}} [ D ( {x}_{D , Fake} ) ] \qquad ( Formula 2 )$$

(x_{D,Real} denotes a real data set consisting of the operation data, the state data, and the output measurement value of the motor, and x_{D,Fake} denotes a virtual data sample consisting of the operation data, the state data, and the output estimated value of the motor.)

In the artificial neural network model 20, the generator 21 is trained to deceive the discriminator 22, which distinguishes the spatiotemporal characteristics of x_{D,Real} and x_{D,Fake}. Accordingly, the generator 21 may generate the estimated value for following the output of the motor of the column EPS system in a normal state.

In this regard, a loss function for GAN training may be defined as Formula 3 below.

$${L}_{G} = \frac{1}{N} \sum \vert {y}_{G} - {\hat{y}}_{G} \vert + 0.001 \times \frac{1}{N} \sum [ - D ( {x}_{D , Fake} ) ] , \\ {L}_{D} = \frac{1}{N} \sum [ D ( {x}_{D , Fake} ) - D ( {x}_{D , Real} ) ] + 10 \times \frac{1}{N} \sum [ {( {‖ {∇}_{{x}_{D , Fake}} D ( {x}_{D , Fake} ) ‖}_{2} - 1 )}^{2} ] \qquad ( Formula 3 )$$

(N denotes a size of a batch, L_{G} denotes a loss function of the generator, and L_{D} denotes a loss function of the discriminator.)

The first term of a loss of the generator 21 corresponds to a loss L_{MAE} of a mean absolute error of supervised training. The remaining term of the loss of the generator 21 together with a loss of the discriminator 22 constitute a loss function L_{GAN} of the GAN.

In an embodiment of the present disclosure, the following may be considered to reflect the dynamic characteristics of the column EPS system in a loss function.

First, the output of the motor in the column EPS system may be obtained as Formula 4.

$${T}_{motor} = {T}_{Load} - {T}_{Steering} \qquad ( Formula 4 )$$

(Tₘₒₜₒᵣ denotes the output of the motor, T_{Load} denotes a force acting on a tire, and T_{Steering} denotes a steering force of the driver.)

Meanwhile, T_{Load} in Formula 4 may be defined as a function of an input signal of the ECU by the Dugoff tire model. Specifically, T_{Load} in Formula 4 may be defined as a function shown in Formula 5 below.

$${T}_{Load} = f ( {∅}_{ECU} ) = ( {δ}_{1} sin \frac{{θ}_{sw}}{n} + {δ}_{2} cos \frac{{θ}_{sw}}{n} ) + {δ}_{3} \qquad ( Formula 5 )$$

(Ø_{ECU} denotes the input signal of the ECU of the vehicle, θ_{sw}, denotes a steering angle of the vehicle, and n denotes a given value.)

In Formula 5, δ₁ and δ₂ represent the model-related uncertainty, and δ₃ represents the uncertainty of the system. Meanwhile, the input signal Ø_{ECU} is a signal that the ECU of the vehicle can receive or measure through the CAN. The output value of the motor may be derived by subtracting a steering force (steering torque) of the driver from T_{Load} obtained through the function in Formula 5.

The dynamic characteristics of the column EPS system may be defined as Equation 4 and Equation 5 above. The dynamic characteristics of the column EPS system may be considered as a physics-based loss function of the artificial neural network model 20.

Through the above-described procedure, the processor 120 may obtain the output estimated value of the motor of the column EPS system.

Further, the processor 120 compares the estimated value obtained in this way with a real output measurement value of the motor. The processor 120 may compare the estimated value with the measurement value and detect an abnormality of the motor 18.

The measurement value may be the command generated by the ECU 17, which is described above regarding FIG. 1. The estimated value obtained by using the artificial neural network model 20 can be regarded as the actual output of the motor 18. Therefore, the processor 120 can detects an abnormality of the motor 18 by comparing the estimated value with the measurement value.

The processor 120 may execute the one or more instructions to input error data related to a difference between the estimated value and the measurement value into an abnormality detection model 30 and determine whether the motor of the column EPS is abnormal. For example, the abnormality detection model 30 may use a one-class support vector machine (OCSVM) algorithm.

There may be a plurality of data sets including the operation data, the state data, the measurement value, and the estimated value. The error data may include a mean and standard deviation of errors between the measurement value and the estimated value that are obtained from each of the plurality of data sets, a maximum absolute error between the measurement value and the estimated value of the plurality of data sets, and a discrimination value of a discriminator for the measurement data of the plurality of data sets.

As described above, the measurement data may include the operation data, the state data, and the measurement value.

The plurality of data sets including the measurement value and the estimated value may be treated as one batch. For example, 100 to 150 data sets (as a specific example, 128 data sets) may be treated as one batch, and the error data may be obtained for each batch.

The error data obtained for one batch may be input to the abnormality detection model 30. Further, the level of the abnormality of the motor (degradation in performance of the motor) may be detected based on an output (characteristic) obtained from the abnormality detection model 30 that receives the error data.

Regarding an anomaly detection metric, an F1 score given as Formula 6 below may be considered.

$$F 1 = \frac{2 \times TP}{2 \times TP + FP + FN} \qquad ( Formula 6 )$$

(TP denotes true positive, FP denotes false positive, and FN denotes false negative, wherein positive indicates degradation in performance of the motor.)

As described above, the discriminator 22 may calculate not only the discrimination value for the measurement data included in the data set, but also the discrimination value for the estimate data included in the data set. The estimate data may include the operation data, the state data, and the estimated value. The discrimination value of the discriminator 22 for the estimate data of the data set may be provided as feedback to the generator 21 of the artificial neural network model 20 and used for training.

Until now, the configuration of the device 100 for detecting the abnormality of the motor of the column EPS according to the embodiment of the present disclosure has been described in detail. Hereinafter, the operation of the device 100 for detecting the abnormality of the motor of the column EPS will be described.

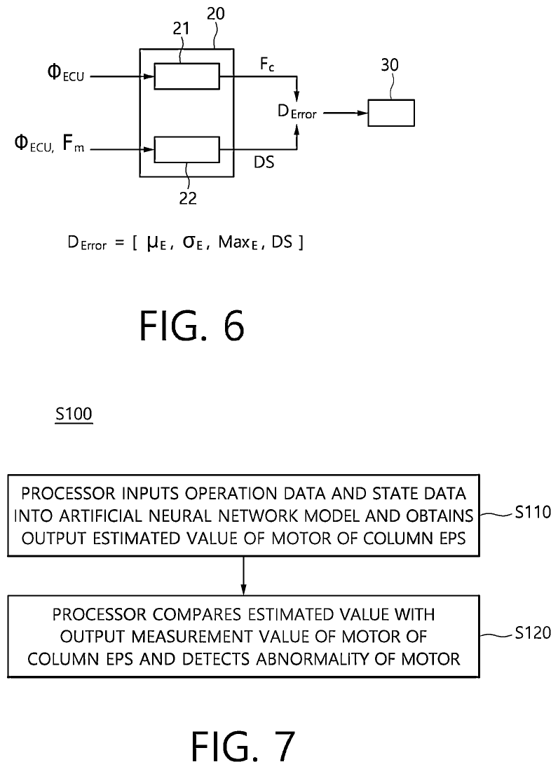

FIG. 6 is a diagram illustrating an operation of the device for detecting the abnormality of the motor of the column EPS according to the embodiment of the present disclosure.

Referring to FIG. 6, the device 100 for detecting the abnormality of the motor of the column EPS according to the embodiment of the present disclosure may operate as follows.

First, the memory 110 stores an input signal Ø_{ECU} obtained from the EPS system of the vehicle and an output measurement value Fₘ of the motor of the column EPS.

Here, the input signal Ø_{ECU} includes operation data and state data. In an embodiment of the present disclosure, the input signal Ø_{ECU} may include a steering angle, a steering angular velocity, a steering torque, a speed of the vehicle, a lateral acceleration of the vehicle, a yaw rate of the vehicle, and a wheel speed of the vehicle.

Meanwhile, a plurality of input signals Ø_{ECU} and a plurality of output measurement values Fₘ of the motor of the column EPS may be treated as one batch. That is, in an embodiment of the present disclosure, data processing and calculations may be performed in units of data batches.

Next, the processor 120 executes the one or more instructions to input the input signal Ø_{ECU} into the artificial neural network model 20 and obtain an output estimated value Fₛ of the motor of the column EPS output by the artificial neural network model 20. More specifically, the processor 120 may input the input signal Ø_{ECU} into the generator 21 of the artificial neural network model 20 and obtain the output estimated value Fₛ of the motor of the column EPS output by the generator 21.

Further, the processor 120 executes the one or more instructions to input the input signal Ø_{ECU} and the output measurement value Fₘ of the motor of the column EPS into the artificial neural network model 20 and obtain a discrimination value DS. More specifically, the processor 120 may input measurement data including the input signal Ø_{ECU} and the output measurement value Fₘ of the motor of the column EPS into the discriminator 22 of the artificial neural network model 20 and obtain the discrimination value DS output by the discriminator 22 for the measurement data.

Next, the processor 120 outputs error data D_{Error}. The error data D_{Error} may be output for each data batch.

As described above, there are the plurality of data sets including the operation data, the state data, the measurement value, and the estimated value, and the error data D_{Error} may include a mean μ_{E} and a standard deviation σ_{E} of errors between the measurement value and the estimated value that are obtained from each of the plurality of data sets, a maximum absolute error Max_{E} between the measurement value and the estimated value of the plurality of data sets, and the discrimination value DS of the discriminator 22 for the measurement data obtained from the plurality of data sets.

Lastly, the processor 120 may execute the one or more instructions to input the error data D_{Error} into the abnormality detection model 30 and obtain an output of the abnormality detection model 30. As described above, the abnormality detection model 30 may include an OCSVM algorithm.

Based on the output obtained from the abnormality detection model 30 that receives the error data D_{Error}, the processor 120 may detect the level of the abnormality (degradation in performance of the motor) of the motor of the column EPS.

As described above, the device 100 for detecting the abnormality of the motor of the column EPS according to the embodiment of the present disclosure has been described in detail. Hereinafter, a method of detecting an abnormality of a motor of a column EPS will be described.

FIG. 7 is a flowchart of a method of detecting an abnormality of a motor of a column EPS according to an embodiment of the present disclosure.

In a method S100 of detecting the abnormality of the motor of the column EPS according to the embodiment of the present disclosure, an abnormality of the motor 18 disposed in the column EPS system of the vehicle is detected. More specifically, in the method S100 of detecting the abnormality of the motor of the column EPS, an abnormality of the motor that is disposed in the column EPS system of the vehicle to provide an auxiliary steering force to a steering column may be detected.

Referring to FIG. 7, the method S100 of detecting the abnormality of the motor of the column EPS according to the embodiment of the present disclosure may be performed as follows.

First, the processor 120 inputs operation data related to steering wheel operation by the driver and state data indicating a state of the vehicle into the artificial neural network model 20 and obtains an output estimated value of the motor that is output by the artificial neural network model 20 (S110).

The operation data may include at least one of a steering angle, a steering angular velocity, and a steering torque. Further, the state data may include at least one of a speed of the vehicle, a lateral acceleration of the vehicle, a yaw rate of the vehicle, and a wheel speed of the vehicle.

For example, the operation data may include a steering angle, a steering angular velocity, and a steering torque, and the state data may include a speed of the vehicle, a lateral acceleration of the vehicle, a yaw rate of the vehicle, and a wheel speed of the vehicle.

In an embodiment of the present disclosure, the artificial neural network model 20 may include a GAN. In other words, the artificial neural network model 20 may be a deep learning-based neural twin model for the column EPS system of the vehicle.

The artificial neural network model 20 may include a generator 21 and a discriminator 22. The generator 21 receives the operation data and the state data and generates the estimated value. The generator 21 may be composed of a multivariate transformer. Further, the discriminator 22 receives measurement data including the operation data, the state data, and the measurement value and outputs a discrimination value for the measurement data.

In operation S110 of obtaining the estimated value of the motor, the processor 120 may input the operation data and the state data into the generator 21 and obtain the estimated value generated by the generator 21.

Meanwhile, the artificial neural network model 20 is constructed by the generator 21 and the discriminator 22 performing learning, and the data used during the learning may be obtained when the motor 18 of the column EPS system 10 is in a normal state. Accordingly, the estimated value may follow the output measurement value of the motor obtained when the motor 18 is in a normal state.

Next, the processor 120 compares the estimated value with the measurement value and detects an abnormality of the motor 18 (S120).

The processor 120 may execute the one or more instructions to input error data related to a difference between the estimated value and the measurement value into the abnormality detection model 30 and determine whether the motor 18 is abnormal. For example, the abnormality detection model 30 may use an OCSVM algorithm.

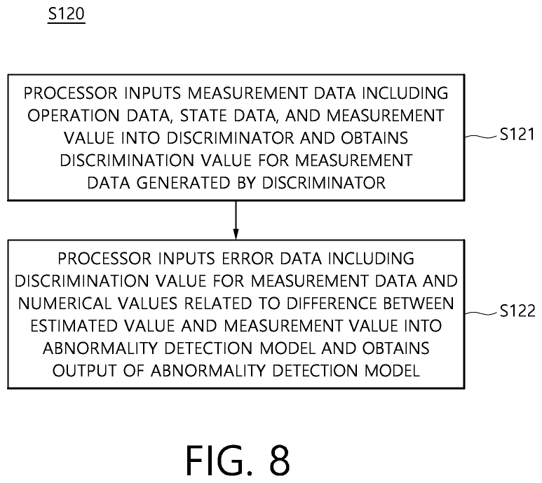

FIG. 8 is a detailed flowchart of an operation of detecting the abnormality of the method of detecting the abnormality of the motor of the column EPS according to the embodiment of the present disclosure.

Referring to FIG. 8, the operation S120 of detecting the abnormality of the motor may be performed as follows.

First, the processor 120 inputs measurement data including the operation data, the state data, and the output measurement value of the motor into the discriminator 22 and obtains a discrimination value for the measurement data generated by the discriminator 22 (S121).

Next, the processor 120 inputs error data including the discrimination value for the measurement data and numerical values related to a difference between the estimated value and the measurement value into the abnormality detection model 30 and obtains an output of the abnormality detection model 30 (S122).

There may be a plurality of data sets including the input data, the measurement value, and the estimated value. The error data may include a mean and standard deviation of errors between the measurement value and the estimated value that are obtained from each of the plurality of data sets, a maximum absolute error between the measurement value and the estimated value of the plurality of data sets, and a discrimination value of the discriminator for the measurement data of the plurality of data sets.

More specifically, the plurality of data sets including the measurement value and the estimated value may be treated as one batch. For example, 100 to 150 data sets (as a specific example, 128 data sets) may be treated as one batch, and the error data may be obtained for each batch.

The error data obtained for one batch may be input to the abnormality detection model 30. Further, the level of the abnormality of the motor (degradation in performance of the motor) may be detected based on an output (characteristic) obtained from the abnormality detection model 30 that receives the error data.

Regarding the anomaly detection metric, the F1 score described above may be considered.

Meanwhile, the present disclosure additionally provides a non-transitory computer-readable storage medium storing a program for performing the method of detecting the abnormality of the motor of the column EPS. More specifically, the present disclosure may provide a non-transitory computer-readable storage medium in which a program including at least one instruction for performing the method of detecting the abnormality of the motor of the column EPS is stored.

In this case, the instruction may include not only machine code generated by a compiler but also high-level language code executable by a computer.

The non-transitory computer-readable storage medium may include a magnetic medium such as a hard disk, a floppy disk, or a magnetic tape, an optical medium such as a CD-ROM or a DVD, a magneto-optical medium such as a floptical disk, or a hardware device configured to store and execute program instructions, such as a ROM, a RAM, a flash memory, etc.

As a result of a simulation, it was found that according to the present disclosure, a decrease up to 10% of a maximum output of the motor of the EPS system can be predicted with the performance of an F1 score of 0.85 or higher. In other words, according to the present disclosure, the level of degradation of the motor can be accurately predicted before the motor disposed in the column EPS system of the vehicle completely fails.

According to the present disclosure, it is possible to predict an abnormality of the motor of the column EPS in advance before a failure of the motor of the column EPS system occurs. As a result, it is possible to take proactive measures before a failure of the motor occurs and it is possible to prevent the failure of the motor and the risks that may arise therefrom.

In this way, the present disclosure provides the estimation of the future operation and remaining useful life of the system and the prognostic diagnosis suitable for predictive maintenance applications. Accordingly, proactive measures and maintenance can be effectively guided before a failure of the motor of the column EPS of the vehicle occurs.

According to the above configuration, in the device and method for detecting the abnormality of the motor of the column EPS system, and the non-transitory computer-readable storage medium storing a program for performing the method according to an aspect of the present disclosure, it is possible to prognosticate degradation in performance of the motor before a failure of the motor disposed in the column EPS system occurs based on an artificial intelligence-based digital twin algorithm.

Further, in the device and method for detecting the abnormality of the motor of the column EPS system, and the non-transitory computer-readable storage medium storing a program for performing the method according to an aspect of the present disclosure, it is possible to predict degradation in performance of the motor of the column EPS using signals of a CAN of the vehicle without a separate additional sensor.

It should be understood that the effects of the present disclosure are not limited to the above-described effects, and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A device comprising:
a memory configured to store one or more instructions; and
a processor configured to detect an abnormality of a motor of a column electric power steering (EPS) configured to provide an auxiliary steering force to a steering column of the vehicle and execute the one or more instructions comprising:
inputting operation data related to steering wheel operation by a driver of the vehicle and state data indicating a state of the vehicle into an artificial neural network model to obtain at least one estimated value of an output of the motor from the artificial neural network model, comparing the estimated value of the output of the motor estimated by the artificial neural network model with at least one measured value of the output of the motor sensed by a sensor, and
detecting the abnormality of the motor of the EPS based on comparison result between the estimated value of the output of the motor estimated by the artificial neural network model and the measured value of the output of the motor sensed by the sensor.

2. The device of claim 1, wherein the operation data related to the steering wheel operation by the driver includes at least one of a steering angle, a steering angular velocity, and a steering torque.

3. The device of claim 1, wherein the state data indicating the state of the vehicle includes at least one of a speed of the vehicle, a lateral acceleration of the vehicle, a yaw rate of the vehicle, and a wheel speed of the vehicle.

4. The device of claim 1, wherein the operation data and the state data comprise signals that are obtainable through a controller area network (CAN) of the vehicle.

5. The device of claim 1, wherein the artificial neural network model includes a generative adversarial network (GAN) including a generator configured to receive the operation data related to the steering wheel operation by the driver and the state data indicating the state of the vehicle and generate the estimated value of the output of the motor.

6. The device of claim 5, wherein the artificial neural network model further includes a discriminator configured to receive measurement data including the operation data, the state data, and the measured value of the output of the motor and output a discrimination value for the measurement data.

7. The device of claim 6, wherein the processor is configured to input error data related to a difference between the estimated value of the output of the motor estimated by the artificial neural network model and the measured value of the output of the motor sensed by the sensor into an abnormality detection model to detect the abnormality of the motor.

8. The device of claim 7, wherein the abnormality detection model uses a one-class support vector machine (OCSVM) algorithm.

9. The device of claim 7, wherein:
the at least one estimated value of the output of the motor estimated by the artificial neural network model comprises a plurality of estimated values, the at least one measured value of the output of the motor sensed by the sensor comprises a plurality of measured values, and a plurality of data sets include the operation data, the state data, the plurality of measured values, and the plurality of estimated values; and
the error data input into the abnormality detection model includes a mean and standard deviation of errors between the plurality of measured values and the plurality of estimated values that are obtained from the plurality of data sets, a maximum absolute error among the errors between the plurality of measured values and the plurality of estimated values of the plurality of data sets, and a discrimination value of the discriminator for the measurement data.

10. The device of claim 6, wherein the discriminator is configured to additionally receive estimate data including the operation data related to the steering wheel operation, the state data indicating the state of the vehicle, and the estimated value of the output of the motor estimated by the artificial neural network model, and additionally output discrimination value for the estimate data.

11. The device of claim 10, wherein:
the artificial neural network model has the generator and the discriminator alternately performing learning, and
the artificial neural network model is configured to perform the learning using the operation data, the state data, and the measured value which are obtained when the motor is in a normal state.

12. A method of detecting an abnormality of a motor of a column electric power steering (EPS) configured to provide an auxiliary steering force to a steering column of a vehicle, the method comprising:
obtaining, by a processor, at least one estimated value of an output of the motor from the artificial neural network model by inputting operation data related to steering wheel operation by a driver of the vehicle and state data indicating a state of the vehicle into the artificial neural network model; and
detecting, by the processor, the abnormality of the motor by comparing the estimated value of the output of the motor estimated by the artificial neural network model with at least one measured value of the output of the motor sensed by a sensor.

13. The method of claim 12, wherein the operation data related to the steering wheel operation by the driver includes at least one of a steering angle, a steering angular velocity, and a steering torque.

14. The method of claim 12, wherein the state data indicating the state of the vehicle includes at least one of a speed of the vehicle, a lateral acceleration of the vehicle, a yaw rate of the vehicle, and a wheel speed of the vehicle.

15. The method of claim 12, wherein the artificial neural network model comprises a generative adversarial network (GAN) including:
a generator configured to receive the operation data related to the steering wheel operation by the driver and the state data indicating the state of the vehicle and generate the estimated value of the output of the motor, and
a discriminator configured to receive measurement data including the operation data, the state data, and the measured value of the output of the motor and output a discrimination value for the measurement data.

16. The method of claim 15, wherein the obtaining of the at least one estimated value of the output of the motor from the artificial neural network model comprises inputting the operation data and the state data into the generator and obtaining the estimated value of the output of the motor generated by the generator.

17. The method of claim 16, wherein the detecting of the abnormality of the motor includes:
inputting, by the processor, measurement data including the operation data, the state data, and the measured value of the output of the motor into the discriminator and obtaining, by the processor, the discrimination value for the measurement data generated by the discriminator; and
inputting, by the processor, error data including the discrimination value for the measurement data and a value related to a difference between the estimated value and the measured value into an abnormality detection model and obtaining, by the processor, an output of the abnormality detection model.

18. The method of claim 17, wherein:
the at least one estimated value of the output of the motor estimated by the artificial neural network model comprises a plurality of estimated values, the at least one measured value of the output of the motor sensed by the sensor comprises a plurality of measured values, and a plurality of data sets include the operation data, the state data, the plurality of estimated values, and the plurality of measured values; and
the error data input into the abnormality detection model includes a mean and standard deviation of errors between the plurality of measured values and the plurality of estimated values that are obtained from the plurality of data sets, a maximum absolute error among the errors between the plurality of measured values and the plurality of estimated values of the plurality of data sets, and a discrimination value of the discriminator for the measurement data.

19. The method of claim 15, wherein:
the artificial neural network model has the generator and the discriminator alternately performing learning, and
the artificial neural network model is configured to perform the learning using the operation data, the state data, and the measured value which are obtained when the motor is in a normal state.

20. A non-transitory computer-readable medium configured to store at least one instruction, that when executed by a processor, causes the processor to perform operations of detecting an abnormality of a motor of a column electric power steering (EPS) configured to provide an auxiliary steering force to a steering column of a vehicle, the operations comprising:
obtaining at least one estimated value of an output of the motor from the artificial neural network model by inputting operation data related to steering wheel operation by a driver of the vehicle and state data indicating a state of the vehicle into the artificial neural network model; and
detecting the abnormality of the motor by comparing the estimated value of the output of the motor estimated by the artificial neural network model with at least one measured value of the output of the motor sensed by a sensor.
